(19) United States
(12) Patent Application Publication
(10) Pub. No.: US 2013/0257514 A1
(43) Pub. Date: Oct. 3, 2013

(54) SOURCE-FOLLOWER BASED VOLTAGE MODE TRANSMITTER

(71) Applicants: Matthew D. Rowley, Parker, TX (US); Rajarshi Mukhopadhyay, Allen, TX (US)

(72) Inventors: Matthew D. Rowley, Parker, TX (US); Rajarshi Mukhopadhyay, Allen, TX (US)

(73) Assignee: Texas Instruments Incorporated, Dallas, TX (US)

(21) Appl. No.: 13/435,578

(22) Filed: Mar. 30, 2012

(51) Int. Cl. H03K 17/687

(52) U.S. Cl. 327/424

(57) ABSTRACT

An apparatus is provided. A first switch is coupled between first and third nodes in an H-bridge. A second switch is coupled between first and fourth nodes in the H-bridge. A third switch is coupled between the second and third nodes. A fourth switch is coupled between second and fourth nodes in the H-bridge. A first source-follower is coupled to the first node of the H-bridge and the first supply rail, and the first source-follower is configured to receive a first reference signal. A second source-follower is coupled to the second node of the H-bridge and the second supply rail, and the second source-follower is configured to receive a second reference signal.

### TECHNICAL FIELD

The invention relates generally to transmitter and, more particularly, to voltage mode transmitter having an H-bridge that uses source-followers.

### BACKGROUND

Turning to FIG. 1, an example conventional driver 100 can be seen. In operation, controller 102 provides complementary drive or control signals to H-bridge 104 (which generally comprises transistors Q1 to Q4 and capacitors C1 and C2). Specifically, these complementary signals are provided to transistor pair Q1 and Q2 (which, as shown, are PMOS transistors) and transistor pair Q3 and Q4 (which, as shown, are NMOS transistors) in order to generate output signals for resistors R1 and R2 (which are typically impedance matching resistors) and the transmission channel (not shown). This means that controller 102 provides a logic high or “1” signal to transistors Q1 and Q4 (while providing a logic low or “0” signal to transistors Q2 and Q3) to create one current path and visa versa for another current path. With either current path, there is a loss that occurs as result of using transistors Q5 and Q6; namely, there is high output impedance and a slow response due to transistors Q5 and Q6 operating as current sources. Therefore, there is a need for a driver having improved performance.

Some examples of conventional circuits are: U.S. Pat. No. 6,917,169; U.S. Pat. No. 5,689,144; U.S. Patent Pre-Grant Publ. No. 2008/0252372; and Krenzket et al., “A 36-V H-BRIDGE DRIVER INTERFACE IN A STANDARD 0.35-μm CMOS PROCESS,” IEEE Intl. Symposium on Circuits and Systems 2005, Vol. 4, May 23-26, 2005, pp. 3651-3554.

### SUMMARY

An embodiment of the present invention, accordingly, provides an apparatus. The apparatus comprises a first supply rail; a second supply rail; an H-bridge having: a first node; a second node; a third node; a fourth node; a first switch that is coupled between the first and third nodes; a second switch that is coupled between the first and fourth nodes; a third switch that is coupled between the second and third nodes; and a fourth switch that is coupled between the second and fourth nodes; a first source-follower that is coupled to the first node of the H-bridge, that is coupled to the first supply rail, and that is configured to receive a first reference signal; and a second source-follower that is coupled to the second node of the H-bridge, that is coupled to the second supply rail, and that is configured to receive a second reference signal.

In accordance with an embodiment of the present invention, the first and second switches further comprise first and second PMOS transistors, wherein each of the first and second PMOS transistors are coupled to the first node at its source.

In accordance with an embodiment of the present invention, the third and fourth switches further comprise first and second NMOS transistors, wherein each of the first and second NMOS transistors are coupled to the second node at its source.

In accordance with an embodiment of the present invention, the first source-follower further comprises a third NMOS transistor that is coupled to the first node at its source and body, that is coupled to the first supply rail at its drain, and that is configured to receive the first reference signal at its gate.

In accordance with an embodiment of the present invention, the second source-follower further comprises a third PMOS transistor that is coupled to the second node at its source and body, that is coupled to the second supply rail at its drain, and that is configured to receive the second reference signal at its gate.

In accordance with an embodiment of the present invention, the third NMOS and third PMOS transistors are depletion mode transistors.

In accordance with an embodiment of the present invention, an apparatus is provided. The apparatus comprises a first supply rail; a second supply rail; a transmitter having: a transmit circuit; an H-bridge having: a first node; a second node; a third node; a fourth node; a first switch that is coupled between the first and third nodes and that is controlled by the transmit circuit; a second switch that is coupled between the first and fourth nodes and that is controlled by the transmit circuit; a third switch that is coupled between the second and third nodes and that is controlled by the transmit circuit; and a fourth switch that is coupled between the second and fourth nodes and that is controlled by the transmit circuit; a first source-follower that is coupled to the first node of the H-bridge, that is coupled to the first supply rail, and that is configured to receive a first reference signal; and a second source-follower that is coupled to the second node of the H-bridge, that is coupled to the second supply rail, and that is configured to receive a second reference signal; an transmission channel that is coupled to the third and fourth nodes; and a receiver that is coupled to the interconnect.

In accordance with an embodiment of the present invention, the transmit circuit further comprises: an input circuit; and a write circuit that is coupled to the input circuit and the gates of the first and second PMOS transistors and the gates of the first and second NMOS transistors.

In accordance with an embodiment of the present invention, the transmission channel further comprises an interconnect.

In accordance with an embodiment of the present invention, the receiver further comprises a magnetic head.

In accordance with an embodiment of the present invention, the write circuit further comprises a driver that is coupled to the gates of the first and second PMOS transistors and the gates of the first and second NMOS transistors.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a diagram of an example of a conventional H-bridge transmitter;

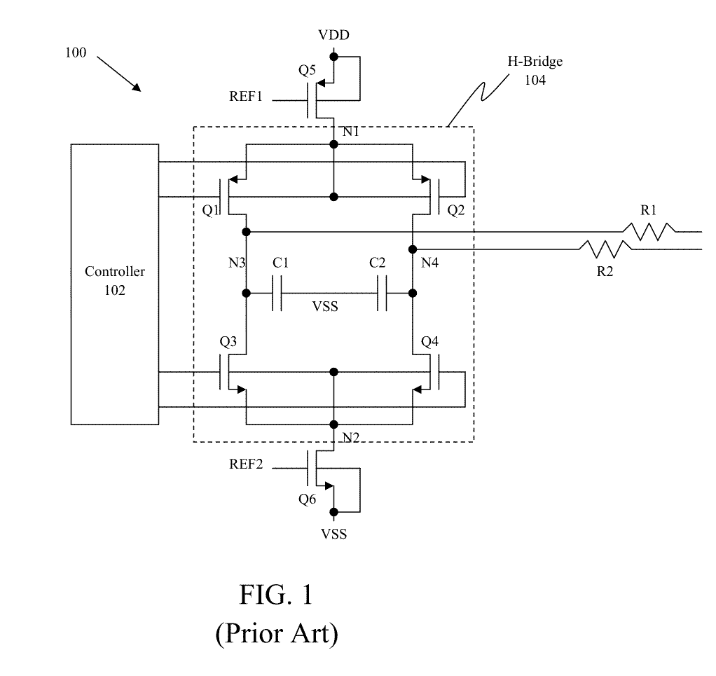

FIG. 2 is a diagram of system in accordance with the present invention;

FIG. 3 is diagram of an example implementation of the system of FIG. 2;

FIG. 4 is a diagram of an example of a driver of the systems of FIGS. 2 and 3; and

FIG. 5 is a diagram comparing the performance of the drivers of FIGS. 1 and 4.

### DETAILED DESCRIPTION

Refer now to the drawings wherein depicted elements are, for the sake of clarity, not necessarily shown to scale and wherein like or similar elements are designated by the same reference numeral through the several views.

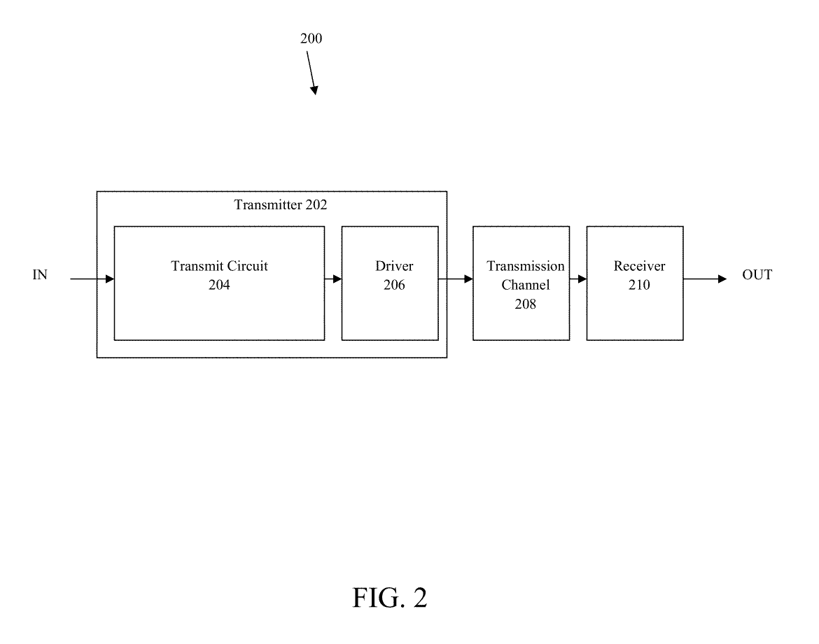

Turning to FIG. 2, an example of a system 200 in accordance with the present invention can be seen. In operation, transmitter 202 (and transmit circuit 204, in particular) receives an input signal IN. The transmit circuit 204 (which, can, for example, perform wave-shaping operations) provides control signals to driver 206 that permit a signal to be driven over the transmission channel 208. The receiver 210 can then generate an output signal OUT based on the signal received from the transmission channel 208.

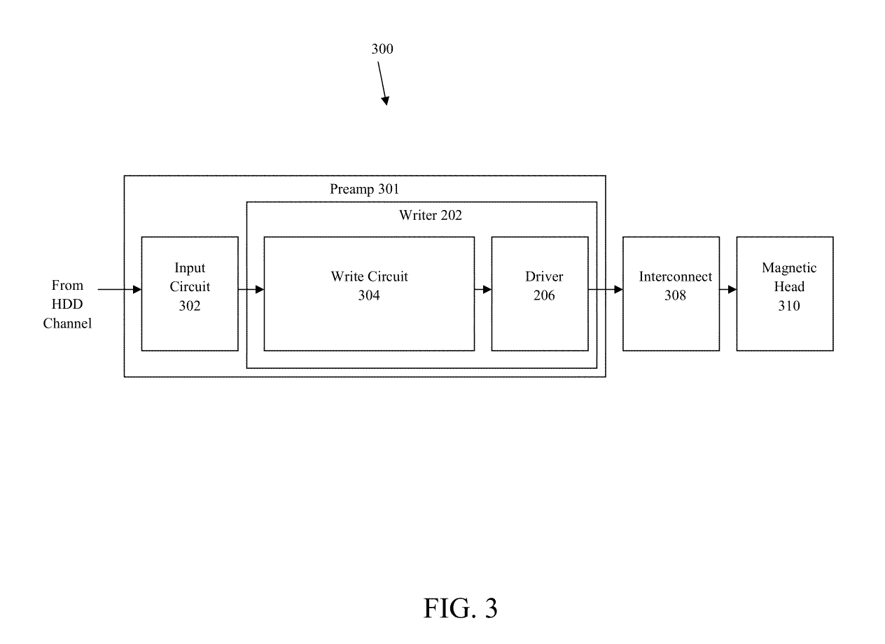

One example implementation of the system 200 can be seen in FIG. 3. In this example, the system 200 is implemented as a write channel for a hard disk drive or HDD (which is labeled 300). For the system 300, a write signal is received from the HDD channel by the preamplifier 301 (namely the input circuit 302). Collectively, the input circuit 302 and write circuit 304 can perform wave-shaping so as to allow driver 206 to transmit a write signal over interconnect 308 to the magnetic head 310. Based on this write signal, the magnetic head 310 can write to an HDD platter.

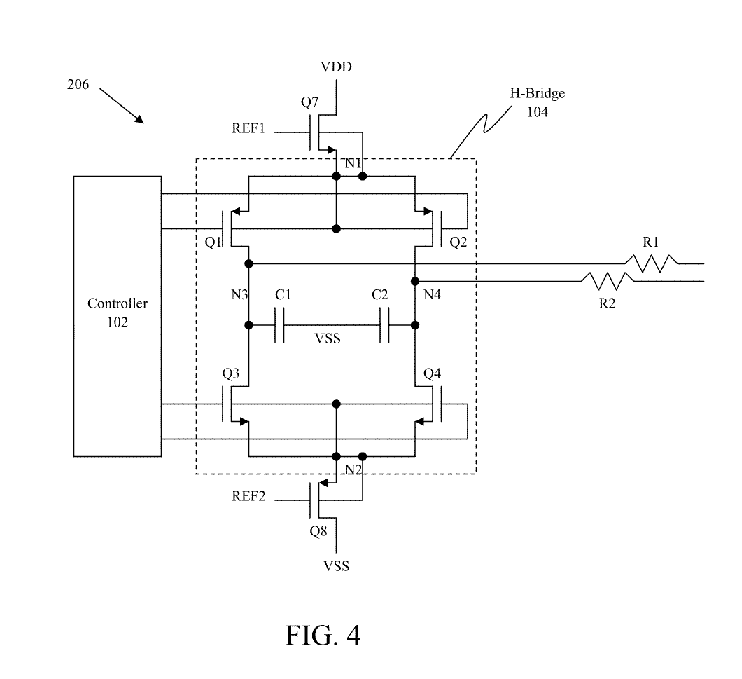

The driver 206 (which can be seen in greater detail in FIG. 4) is used in systems 200 and 300. Driver 206 has a similar construction driver 100, except that current sources (i.e., transistors Q5 and Q6) have been replaced with source-followers (i.e., transistors Q7 and Q8), which are coupled to nodes N1 and N2 of H-bridge 104. Source-followers respond very quickly (compared to current sources) to changes in the source voltage (which occur during switching of H-bridge 104). Since the gates of transistors Q7 and Q8 are generally held at fixed reference voltages REF1 and REF2, any source voltage changes results in an increase of the gate-source voltage of transistors Q7 and Q8, which prompts a rapid increase in drain-to-source current. Thus, driver 206 more rapidly charges and discharges the output nodes N3 and N4 compared to driver 100, improving efficiency.

Moreover, by using source-followers (i.e., transistors Q7 and Q8), the common source impedance Z_{OUT} looking back into the H-bridge 104 is also decreased. Looking back to driver 100, impedance Z_{OUT,100} is:

$${Z}_{OUT , 100} = {Z}_{SWITCH} + {Z}_{CS} = {Z}_{SWITCH} + \frac{{V}_{A}}{{I}_{D}} , \qquad ( 1 )$$

where Z_{SWITCH} is the switch impedance (i.e., on-resistance of one of transistors Q1 to Q4), Z_{CS} is current source impedance, V_{A} is the Early voltage of transistor Q5 or Q6, and I_{D} is the drain current of transistor Q5 or Q6. This means that for an Early voltage of about 10V and a drain current I_{D} of about 50 mA, impedance Z_{OUT,100} is about 200Ω (which is very high). With driver 206, the impedance Z_{OUT,206} is

$$\begin{matrix}{Z}_{OUT , 200} = {Z}_{SWITCH} + {Z}_{SF} = {Z}_{SWITCH} + \frac{1}{{g}_{m}} \\ = {Z}_{SWITCH} + \frac{1}{\sqrt{\frac{2 W}{L} {C}_{OX} μ {I}_{D}}} ,\end{matrix} \qquad ( 2 )$$

where Z_{SF} is source-follower impedance, W/L is the aspect ratio of transistor Q7 or Q8, C_{OX} is the oxide unit capacitance of transistor Q7 or Q8, μ is the carrier mobility, and I_{D} is the drain current of transistor Q7 or Q8. The impedance Z_{OUT,206} is comparative much smaller, being about 1-5Ω with a drain current I_{D} of about 10 mA. This lower impedance can, therefore, move the resulting parasitic pole out to a higher frequency so as to permit higher frequency operation.

To further improve performance, transistors Q7 and Q8 can be depletion mode transistors. Depletion mode devices (i.e., depletion mode NMOS or PMOS transistors) have a negative threshold voltage V_{T}. This allows the source-followers (i.e., transistors Q7 and Q8) to achieve a maximum output swing (which, theoretically, is a dynamic range from the voltage on rail VSS plus a drain-source voltage drop across transistor Q8 to the voltage on rail VDD minus a drain-source voltage drop across transistor Q7) without having to provide reference voltage REF1 and REF2 that exceed the voltages on rails VDD and VSS (which is usually accomplished with charge pumps).

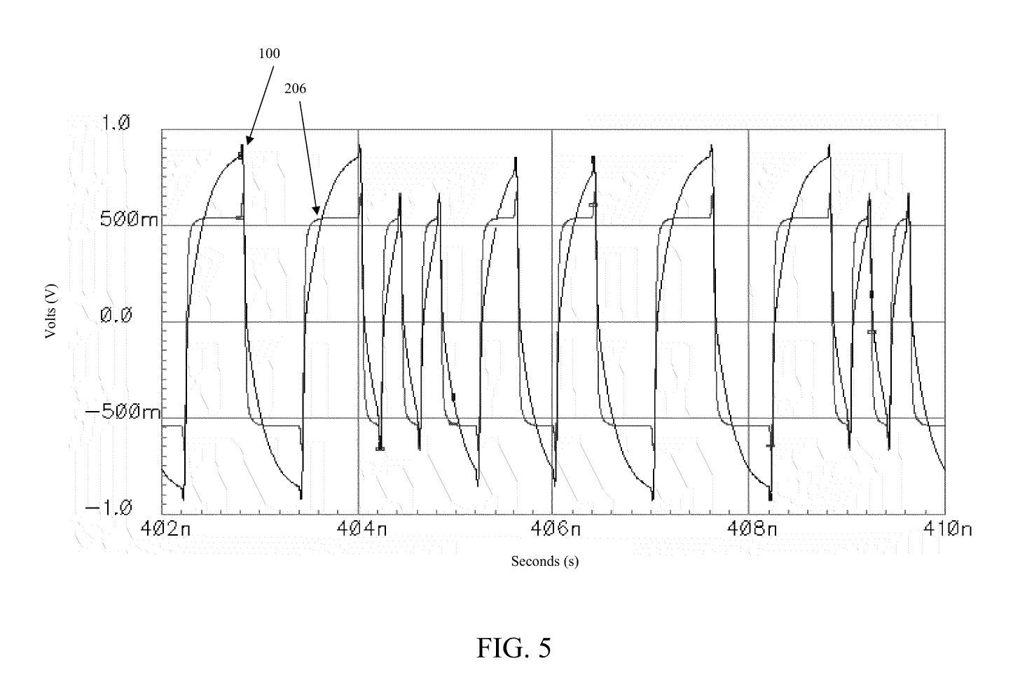

Turning to FIG. 5, a comparison of the drivers 100 and 206 can be seen. As shown, driver 206 settles much more quickly than driver 100. As a result the efficiency of driver 206 is greatly improved over that of driver 100.

Having thus described the present invention by reference to certain of its preferred embodiments, it is noted that the embodiments disclosed are illustrative rather than limiting in nature and that a wide range of variations, modifications, changes, and substitutions are contemplated in the foregoing disclosure and, in some instances, some features of the present invention may be employed without a corresponding use of the other features. Accordingly, it is appropriate that the appended claims be construed broadly and in a manner consistent with the scope of the invention.

1. An apparatus comprising:
a first supply rail;
a second supply rail;
an H-bridge having:
a first node;
a second node;
a third node;
a fourth node;
a first switch that is coupled between the first and third nodes;
a second switch that is coupled between the first and fourth nodes;
a third switch that is coupled between the second and third nodes; and
a fourth switch that is coupled between the second and fourth nodes;
a first source-follower that is coupled to the first node of the H-bridge, that is coupled to the first supply rail, and that is configured to receive a first reference signal; and
a second source-follower that is coupled to the second node of the H-bridge, that is coupled to the second supply rail, and that is configured to receive a second reference signal.

2. The apparatus of claim 1, wherein the first and second switches further comprise first and second PMOS transistors, wherein each of the first and second PMOS transistors are coupled to the first node at its source.

3. The apparatus of claim 2, wherein the third and fourth switches further comprise first and second NMOS transistors, wherein each of the first and second NMOS transistors are coupled to the second node at its source.

4. The apparatus of claim 3, wherein the first source-follower further comprises a third NMOS transistor that is coupled to the first node at its source and body, that is coupled to the first supply rail at its drain, and that is configured to receive the first reference signal at its gate.

5. The apparatus of claim 4, wherein the second source-follower further comprises a third PMOS transistor that is coupled to the second node at its source and body, that is coupled to the second supply rail at its drain, and that is configured to receive the second reference signal at its gate.

6. The apparatus of claim 5, wherein the third NMOS and third PMOS transistors are depletion mode transistors.

7. An apparatus comprising:
a first supply rail;
a second supply rail;
a transmitter having:
a transmit circuit;
an H-bridge having:
a first node;
a second node;
a third node;
a fourth node;
a first switch that is coupled between the first and third nodes and that is controlled by the transmit circuit;
a second switch that is coupled between the first and fourth nodes and that is controlled by the transmit circuit;
a third switch that is coupled between the second and third nodes and that is controlled by the transmit circuit; and
a fourth switch that is coupled between the second and fourth nodes and that is controlled by the transmit circuit;
a first source-follower that is coupled to the first node of the H-bridge, that is coupled to the first supply rail, and that is configured to receive a first reference signal; and
a second source-follower that is coupled to the second node of the H-bridge, that is coupled to the second supply rail, and that is configured to receive a second reference signal;
an transmission channel that is coupled to the third and fourth nodes; and
a receiver that is coupled to the interconnect.

8. The apparatus of claim 7, wherein the first and second switches further comprise first and second PMOS transistors, wherein each of the first and second PMOS transistors are coupled to the first node at its source.

9. The apparatus of claim 8, wherein the third and fourth switches further comprise first and second NMOS transistors, wherein each of the first and second NMOS transistors are coupled to the second node at its source.

10. The apparatus of claim 9, wherein the first source-follower further comprises a third NMOS transistor that is coupled to the first node at its source and body, that is coupled to the first supply rail at its drain, and that is configured to receive the first reference signal at its gate.

11. The apparatus of claim 10, wherein the second source-follower further comprises a third PMOS transistor that is coupled to the second node at its source and body, that is coupled to the second supply rail at its drain, and that is configured to receive the second reference signal at its gate.

12. The apparatus of claim 11, wherein the third NMOS and third PMOS transistors are depletion mode transistors.

13. The apparatus of claim 12, wherein the transmit circuit further comprises:
an input circuit; and
a write circuit that is coupled to the input circuit and the gates of the first and second PMOS transistors and the gates of the first and second NMOS transistors.

14. The apparatus of claim 14, wherein the transmission channel further comprises an interconnect.

15. The apparatus of claim 14, wherein the receiver further comprises a magnetic head.

16. The apparatus of claim 15, wherein the write circuit further comprises a driver that is coupled to the gates of the first and second PMOS transistors and the gates of the first and second NMOS transistors.
